(19) United States
(12) Patent Application Publication
(10) Pub. No.: US 2025/0308947 A1
(43) Pub. Date: Oct. 2, 2025

(54) METHOD AND WAFER PROCESSING SYSTEM FOR WET ETCHING A SEMICONDUCTOR WAFER

(71) Applicant: Tokyo Electron Limited, Tokyo (JP)

(72) Inventor: Shan HU, Albany, NY (US)

(73) Assignee: Tokyo Electron Limited, Tokyo (JP)

(21) Appl. No.: 18/621,229

(22) Filed: Mar. 29, 2024

(51) Int. Cl. H01L 21/67

(52) U.S. Cl. CPC H01L 21/6708; H01L 21/67051; H01L 21/67248; H01L 21/67253

(57) ABSTRACT

A method and wafer processing system for etching a semiconductor wafer are provided. The method includes determining a portion of a wafer surface of the semiconductor wafer that requires a higher etch rate than a remaining portion of the wafer surface, depositing a liquid etch solution onto the wafer surface of the semiconductor wafer, and applying a heat energy to the liquid etch solution covering the determined portion of the wafer surface to increase a local temperature of the determined portion of the wafer surface and an etch rate of the liquid etch solution covering the determined portion of the wafer surface.

### FIELD OF THE INVENTION

This disclosure relates to etching of semiconductor substrates, and particularly to a method and wafer processing system for wet etching of a semiconductor wafer.

### BACKGROUND

Semiconductor fabrication involves many different steps of depositing, growing, patterning, removal, and cleaning of wafers. Various different materials are added and removed or partially removed, while other materials remain. One removal technique is wet etching, which typically involves immersing a semiconductor wafer into an etch solution or dispensing such a solution onto a wafer surface of the semiconductor wafer. The etch solution, when in contact with the semiconductor wafer, can chemically react with a target material to release it from the semiconductor wafer. The etched material can be typically dissolved in, or physically carried away by, the etch solution.

### SUMMARY

This disclosure provides a method of etching a semiconductor wafer. The method includes determining a portion of a wafer surface of the semiconductor wafer that requires a higher etch rate than a remaining portion of the wafer surface, depositing a liquid etch solution onto the wafer surface of the semiconductor wafer, and applying a heat energy to the liquid etch solution covering the determined portion of the wafer surface to increase a local temperature of the determined portion of the wafer surface and an etch rate of the liquid etch solution covering the determined portion of the wafer surface.

Aspects of this disclosure further provide a wafer processing system for etching a semiconductor wafer. The wafer processing system includes a controller configured to determine a portion of a wafer surface of the semiconductor wafer that requires a higher etch rate than a remaining portion of the wafer surface. The controller can control a chemical dispense nozzle to deposit a liquid etch solution onto the wafer surface of the semiconductor wafer. The controller is further configured to control a heating device to apply a heat energy to the liquid etch solution covering the determined portion of the wafer surface to increase a local temperature of the determined portion of the wafer surface and an etch rate of the liquid etch solution covering the determined portion of the wafer surface.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates a plot of a wet etch rate verse process temperature according to an embodiment of the disclosure.

FIG. 2 illustrates a schematic of a wafer processing system according to an embodiment of the disclosure.

FIG. 3 illustrates an example of patterning a semiconductor wafer according to an embodiment of the disclosure.

FIG. 4 illustrates an example of smoothing a semiconductor wafer according to an embodiment of the disclosure.

FIG. 5 illustrates another example of smoothing a semiconductor wafer according to an embodiment of the disclosure.

FIG. 6 illustrates an example of cleaning a semiconductor wafer according to an embodiment of the disclosure.

FIG. 7 illustrates a schematic of another wafer processing system according to an embodiment of the disclosure.

FIGS. 8A-8C illustrate an example of a wet etching process using a pulse heat energy according to an embodiment of the disclosure.

FIG. 9 illustrates a flowchart outlining a semiconductor process according to an embodiment of the disclosure.

### DETAILED DESCRIPTION

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

In a wet etching process, a semiconductor wafer can be immersed into a liquid etch solution having an etchant, or such a solution can be dispensed onto a surface of the semiconductor wafer. The liquid etch solution, when in contact with the semiconductor wafer, chemically reacts with a target material to release it from the semiconductor wafer. The etched material can be dissolved in, or physically carried away by, the liquid etch solution. A high etch rate of the liquid etch solution can reduce a total etch time while a low etch rate of the liquid etch solution can allow an accurate control of an amount etched from the semiconductor wafer.

According to aspects of the disclosure, a wet etching process can benefit from a non-uniform etch rate of a liquid etch solution. For example, when patterning or smoothing a semiconductor wafer, a first portion of the semiconductor wafer may need a higher etch rate than a second portion of the semiconductor. In such an example, if the liquid etch solution can have a non-uniform etch rate, both a shortened total etch time and an accurate etch control can be achieved for the wet etch process.

Accordingly, this disclosure presents methods and wafer processing systems of providing a liquid etch solution with a non-unform etch rate.

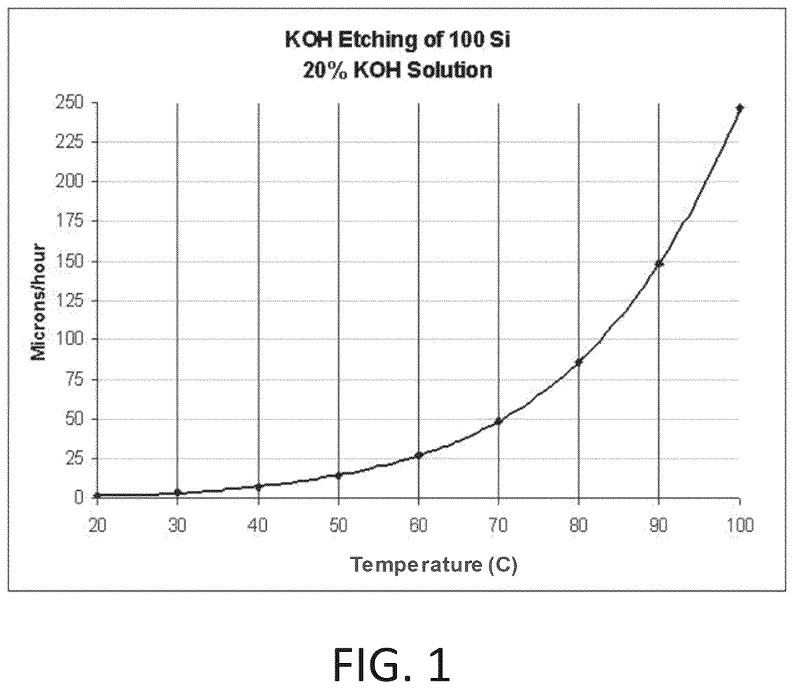

An etch rate of a liquid etch solution can be highly sensitive to a temperature of the liquid etch solution. FIG. 1 illustrates a plot of an etch rate of a liquid etch solution verse a temperature of the liquid etch solution according to an embodiment of the disclosure. The liquid etch solution can be 20% KOH and the etched material can be 100 Silicon. It can be seen that the higher the temperature, the higher the etch rate of the liquid etch solution. To increase the etch rate, the temperature of the liquid etch solution can be increased.

Accordingly, in this disclosure, to provide the liquid etch solution with a non-uniform etch rate, a heat energy can be applied to the liquid etch solution covering a portion of a wafer surface of a semiconductor wafer that requires a higher etch rate than a remaining portion of the wafer surface.

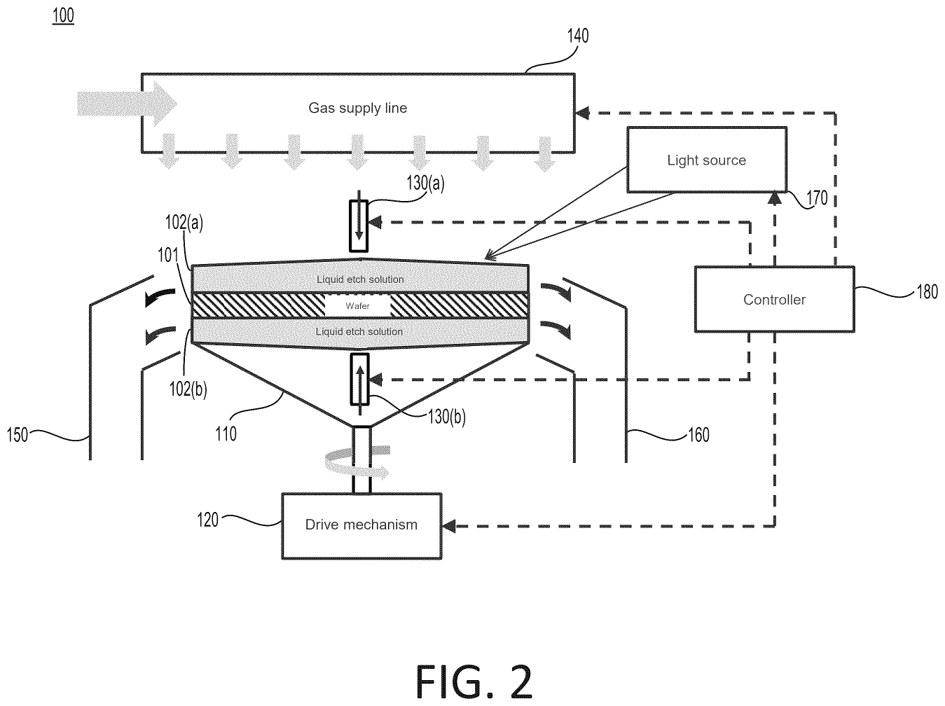

FIG. 2 illustrates a schematic of a wafer processing system 100 that provides a wet etching process according to an embodiment of the disclosure. In the wet etching process, a liquid etch solution with a non-unform etch rate can be provided by applying a heat energy to the liquid etch solution. The wafer processing system 100 can perform the wet etching process to pattern, smooth, and/or clean one or more surfaces of a semiconductor wafer 101.

As shown in FIG. 2, the wafer processing system 100 can include a spin chuck 110, a drive mechanism 120, chemical dispense nozzles 130, a gas supply line 140, a drain line 150, an exhaust line 160, a light source 170, and a controller 180. The wafer processing system 100 can also include one or more other devices (not shown in FIG. 2) that are used in the wet etching process. For example, the wafer processing system 100 can include a temperature sensor or a heat camera to monitor the temperature across the surface of the semiconductor wafer 101.

During the wet etching process, the semiconductor wafer 101 can be supported and secured on a horizontal upper surface of the spin chuck 110. The horizontal upper surface of the spin chuck 110 can provide a suction port for securing the semiconductor wafer 101 to the spin chuck 110 with suction.

After the semiconductor wafer 101 is secured on the horizontal upper surface of the spin chuck 110, a liquid etch solution 102 used for wet etching the semiconductor wafer 101 can be dispensed through the chemical dispense nozzles 130 onto the top and bottom surfaces of the semiconductor wafer 101. For example, the front and back side chemical dispense nozzles 130(a) and 130(b) can dispense the liquid etch solution 102 onto the top and bottom surfaces of the semiconductor wafer 101, respectively.

To provide the liquid etch solution 102 with a non-uniform etch rate, the light source 170 can irradiate a portion of the liquid etch solution 102 to increase a local temperature of the portion of the liquid etch solution 102. Specifically, a portion of the semiconductor wafer 101 that requires a higher etch rate than a remaining portion of the semiconductor wafer 101 can be first determined. Then, an illumination of the light source 170 can be applied onto the liquid etch solution 102 covering the determined portion of the semiconductor wafer 101, so that the temperature of the liquid etch solution 102 covering the determined portion of the semiconductor wafer 101 can be increased, while the temperature of the liquid etch solution 102 covering the remaining portion of the semiconductor wafer 101 can be maintained (or rarely changed). Accordingly, the etch rate of the liquid etch solution 102 covering the determined portion of the semiconductor wafer 101 can be increased, and the determined portion of the semiconductor wafer 101 can be etched faster than the remaining portion of the semiconductor wafer 101.

It is noted that different light frequencies of the light source 170 can have different absorption on different surfaces and liquid etch solutions. When the light passes through the liquid etch solution 102, the light energy can be absorbed by the liquid etch solution 102, heating up a big portion of the liquid etch solution 102 and reducing the resolution of the liquid etch solution 102. To minimize this issue, a light frequency of the light source 170 can be selected such that the portion of the semiconductor wafer 101 that requires a higher etch rate can have a higher light absorption than the liquid etch solution 102. By using such light frequency, most of the light energy can be absorbed by the wafer surface that needs to be etched out and the liquid etch solution 102 just on top of the wafer surface can be heated up.

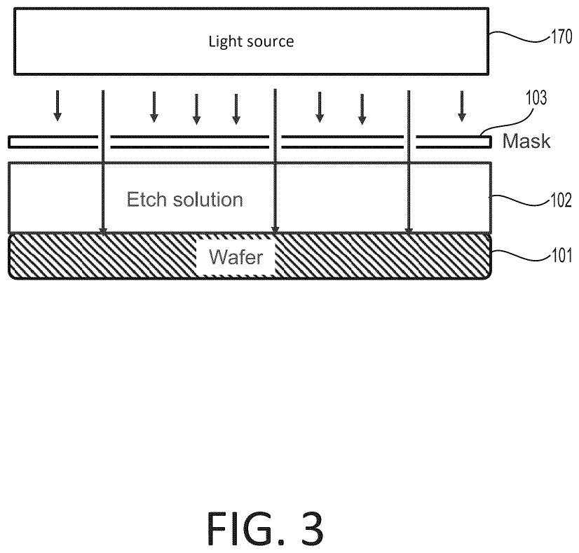

In an embodiment, the illumination of the light source 170 can be applied to pattern the semiconductor wafer 101. FIG. 3 illustrates an example of patterning the semiconductor wafer 101. In FIG. 3, the illumination of the light source 170 can be applied via a patterning mask 103 onto the liquid etch solution 120 covering the determined portion of the semiconductor wafer 101 to form a patterning structure for the semiconductor wafer 101.

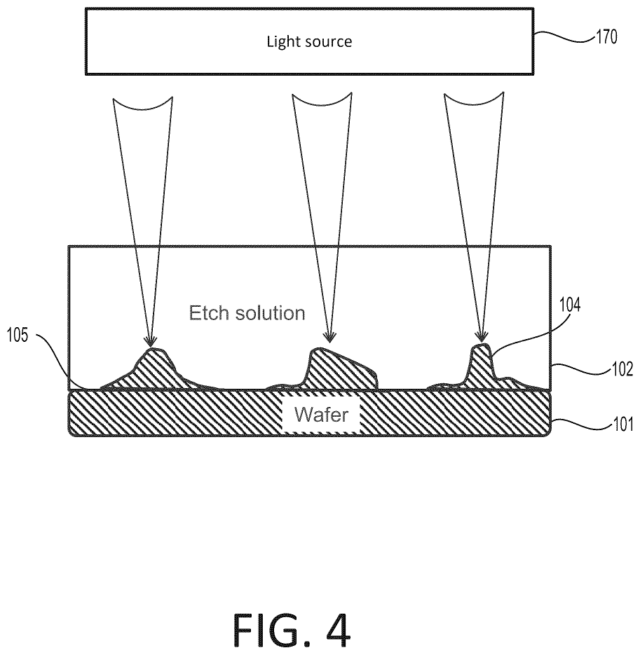

In an embodiment, the illumination of the light source 170 can be applied to smooth the semiconductor wafer 101. FIG. 4 illustrates an example of smoothing the semiconductor wafer 101. In FIG. 4, there are high peak spots 104 on the top surface 105 of the semiconductor wafer 101. To smooth the top surface 105, the etch rate of the liquid etch solution 102 covering the high peak spots 104 needs to be higher than the etch rate of the liquid etch solution 102 covering the remaining portion of the top surface 105. Accordingly, the light source 170 irradiates the liquid etch solution 102 covering the high peak spots 104 on the top surface 105 of the semiconductor wafer 101.

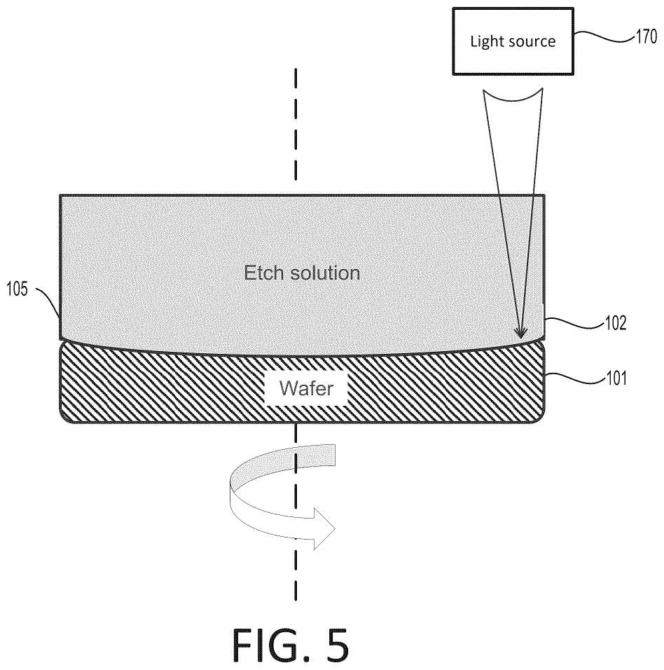

FIG. 5 illustrates another example of smoothing the semiconductor wafer 101. In FIG. 5, the top surface 105 of the semiconductor wafer 101 is not flat (or has a non-uniform thick layer) and in a bowl shape (i.e., the thickness of the semiconductor wafer 101 is gradually reduced from the edge of the top surface 105 to the center of the top surface 105). To flat the top surface 105, the illumination of the light source 170 can scan from the liquid etch solution 102 covering the edge of the top surface 105 to the liquid etch solution 102 covering the center of the top surface 105. During the scan of the illumination, the intensity and/or dwelling time of the illumination can be gradually reduced from the edge of the top surface 105 to the center of the top surface 105. In addition, during the scan of the illumination, the semiconductor wafer 101 can be rotated along the axis through the center of the top surface 105 and perpendicular to the top surface 105 of the semiconductor wafer 101.

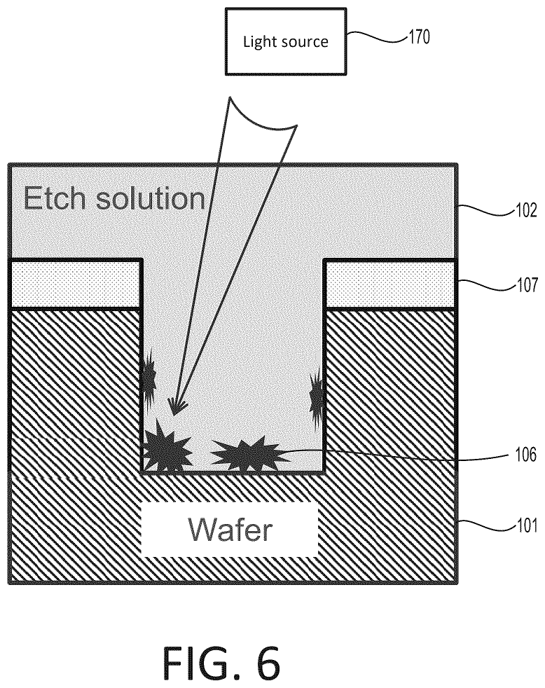

In an embodiment, the illumination of the light source 170 can be applied to clean the semiconductor wafer 101. FIG. 6 illustrates an example of cleaning the semiconductor wafer 101. In FIG. 6, etch residuals 106, which for example are generated by a dry etching process, land inside a trench formed by the dry etching process. For example, the etch residuals 106 can land on a bottom of the trench, in a corner of the trench, and/or on a side wall of the trench. To remove the etch residuals 106, the wet etching process can be applied to the trench. Locations of the etch residuals 106 can be measured by energy dispersive X-ray spectroscopy (EDX) and/or electron energy loss spectroscopy (EELS) for example. Since the locations of the etch residuals 106 can be very similar across the wafers, the etch residuals information of a current wafer can be obtained from a previous processed wafer. Accordingly, the light source 170 can irradiate the bottom, the corner, and/or the side wall of the trench to selectively remove the etch residuals 106. To prevent other portion of the semiconductor wafer 101 from being etched, a protection layer 107 can be deposited on the other portion of the semiconductor wafer 101 before the wet etching process is performed.

It is noted that in the FIGS. 4-5 examples a wafer surface topography of the semiconductor wafer 101 should be measured before the liquid etch solution 102 is dispensed onto the semiconductor wafer 101. The wafer surface topography measurement can be performed by using atomic force microscopy (AFM) for example. Through the wafer surface topography measurement, locations and/or thickness of the high peak spots 104, or the bowl shape of the top surface 105 can be obtained. Based on the wafer surface topography measurement, the controller 180 can determine a dwelling time and a location of the illumination of the light source 170.

During the wet etching process, the spin chuck 110 and the semiconductor wafer 101 can remain stationary (e.g., in the FIG. 3, FIG. 4, and FIG. 6 examples) or be rotated (e.g., in the FIG. 5 example). The rotation of the spin chuck 110 and the semiconductor 101 can be performed by the drive mechanism 120 (e.g., a stepper motor). The drive mechanism 120 can operate at various angular velocities in this disclosure.

In the examples (e.g., FIG. 3 or FIG. 4 example) that require the wafer is stationary, the liquid etch solution 102 can be dispensed onto the semiconductor wafer 101 while the semiconductor wafer 101 is spinning. After the semiconductor wafer 101 is fully covered by the liquid etch solution 102, the rotating of the semiconductor wafer 101 can be gradually stopped. Then, the semiconductor wafer 101 is stationary and fully covered by the liquid etch solution 102 for the duration of the etching time. This process can be referred to as puddle process, which reduces usage of the liquid etch solution 102. After the puddle process, the semiconductor wafer 101 can be rotated again and the liquid etch solution 102 or distilled deionized water (DIW) can be dispensed onto the center of the wafer surface.

In an embodiment, the illumination of the light source 170 can be synchronized to the motion of the semiconductor wafer 101, so that a time-invariant intensity can be achieved for the illumination of the light source 170 on the liquid etch solution 102 covering an area of the semiconductor wafer 101 that requires a higher etch rate. For example, when the light source 170 is a light emitting diode (LED) array, a spatial intensity of the LED array can be synchronized to the motion of the semiconductor wafer 101. If a higher spatial resolution is desired, the light source 170 can be a laser. The laser can be moved and/or scanned over the wafer surface in a motion that provides higher light intensities to the liquid etch solution 102 covering the area of the semiconductor wafer 101 that requires a higher etch rate. Further, the light source 170 can include both the LED array and the laser to allow for a zone flood exposure augmented with a precise laser scanning.

In an embodiment, when the light source 170 includes the LED array, power of individual emitters in the LED array can be adjusted in real time to control the illumination intensity across the surface of the semiconductor wafer 101. The LED array can either be mechanically synchronized to the motion of the wafer, or the array can remain stationary while an intensity of the individual emitters is synchronized to the motion of the wafer.

In an embodiment, when the light source 170 includes the laser, steering optics can be used to raster a laser beam of the laser over the wafer surface. The dwell time of a laser spot on an individual point on the semiconductor wafer 101 controls the etch enhancement at that point. Motion of the laser beam can be synchronized to the motion of the semiconductor wafer 101.

In an embodiment, the intensity of the light source 170 can be spatially varied. The spatial variation in the light intensity can be used to correct a thickness variation across the semiconductor wafer 101. Spatial control over the etch rate can allow for correcting a non-uniform layer thickness across the wafer surface by increasing the etch rate in locations where the semiconductor wafer 101 is thickest, for example.

In an embodiment, the spatial illumination can be based on etch data from a previous etch process. For example, after examining the semiconductor wafer 101, one or more locations that require a higher etch rate can be identified. Then, based on the one or more locations, the spatial illumination in a subsequent wet etch process can be performed.

In an embodiment, the spatial illumination can be based on a real-time measurement, a previous wafer surface metrology measurement using a feed-forward control, or a measurement from a similar wafer. For example, a temperature sensor or a heat camera can monitor temperature across the surface of the semiconductor wafer 101. More light or heat energy can be added to a particular area to counter an evaporative cooling effect or another temperature differential. Irradiation can also be tapered or reduced as the wet etching process approaches an end point.

After wet etching the semiconductor wafer 101, the remaining etch solution on the surfaces of the semiconductor wafer 101 can be spun off to the drain line 150 while the rotating of the semiconductor wafer 101 is still maintained. In an embodiment, the DIW can be dispensed onto the semiconductor wafer 101 to rinse the wafer surface for a certain amount of time so that the wafer surface can always be covered by liquid. After the wafer surface is completely rinsed, the DIW dispensing can be stopped while the semiconductor wafer 101 is still rotating. Then, the wafer surface can be spun dry. In an embodiment, isopropyl alcohol (IPA) can be dispensed onto the semiconductor wafer 101 after the DIW rinse and before the spin dry to prevent pattern collapses on the semiconductor wafer 101. A gas (e.g., clean air or nitrogen) provided by the gas supply line 140 can be used to create a flow pattern to have less particles land onto the wafer surface and to push out any gas into the exhaust line 160. Any gaseous species, such as vapors released from the semiconductor wafer 101 during the wet etching process, can be exhausted by the exhaust line 160 which can be connected to an exhaust unit (e.g., a vacuum pump or another negative pressure-generating device).

It is noted that, except supplying control signals to the light source 170, the controller 180 can also supply control signals to the drive mechanism 120, the chemical dispense nozzles 130, and/or the gas supply line 140.

According to an embodiment of the disclosure, the semiconductor wafer 101 can remain stationary when being irradiated by the light source 170. For example, after the liquid etch solution 102 is dispensed, the rotation of the semiconductor wafer 101 can be gradually stopped. Then, the liquid etch solution 102 can stay on the surfaces of the semiconductor wafer 101 when the semiconductor wafer 101 is stationary.

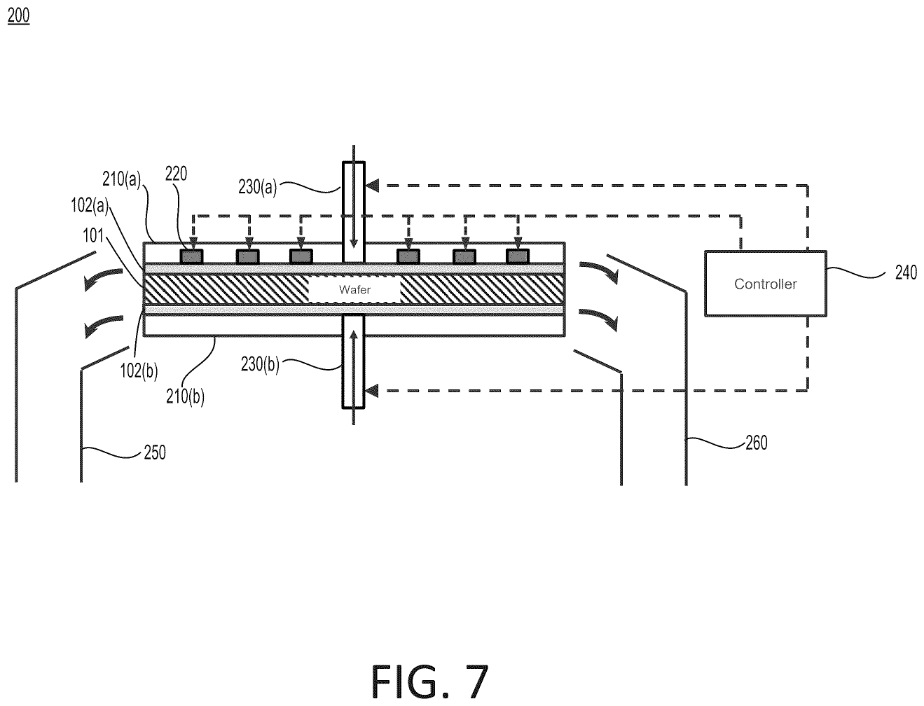

FIG. 7 illustrates a schematic of another wafer processing system 200 according to an embodiment of the disclosure. In the wafer processing system 200, the semiconductor wafer 101 can be always stationary, and the liquid etch solution 102 can be continuously dispensed during wet etching the semiconductor wafer 101. Specifically, the wafer processing system 200 includes functional plates 210 that physically confine the liquid etch solution 102 within a relatively small and enclosed processing space, forcing the liquid etch solution 102 to flow radially across the surfaces of the semiconductor wafer 101 without the need to rotate the semiconductor wafer 101.

As shown in FIG. 7, the semiconductor wafer 101 can be sandwiched between the top and bottom functional plates 210(a) and 210(b) and be supported on the bottom functional plate 210(b).

Similar to the wafer processing system 100, the wafer processing system 200 includes chemical dispense nozzles 230, a controller 240, a drain line 250, and an exhaust line 260. The chemical dispense nozzles 230 can dispense the liquid etch solution 102 onto the surfaces of the semiconductor wafer 101. The liquid etch solution 102 can be dispensed continuously or discontinuously. For example, when using the puddle process, the liquid etch solution 102 can be dispensed discontinuously. After the wet etching process, the DIW can be dispensed to rinse the wafer surface and then the IPA can be dispensed. The drain line 250 can drain any remaining liquid etch solution 120 from the surfaces of the semiconductor wafer 101. A gas (e.g., clean air or nitrogen) can be provided through the chemical dispense nozzles 230 to remove the remaining liquid etch solution 102 and/or the DIW and/or the IPA. The gas can be exhausted by the exhausted line 260. Any gaseous species, such as vapors released from the semiconductor wafer 101 during the wet etching process, can also be exhausted by the exhausted line 260. The controller 240 can provide control signals to the chemical dispense nozzles 230.

In an embodiment, the top functional plate 210(a) can be a heater with an array of tiny heaters 220 (e.g., hot needles) so that the heat energy can be spatially provided to one or more areas of the semiconductor wafer 101 that require a higher etch rate than other areas of the semiconductor wafer 101. The controller 240 can provide control signals to the array of tiny heaters 220.

In an embodiment, the top functional plate 210(a) can be transparent, and the light techniques used in the FIG. 2 example, such as the laser or LED array, can be applied to the FIG. 7 example. Further, the patterning mask used in the FIG. 3 example can also be applied to the FIG. 7 example.

It is noted that any of the controllers 180 in FIGS. 2 and 240 in FIG. 7 described herein can be implemented in a wide variety of manners. For example, any controller can be a computer and/or include one or more programmable integrated circuits that are programmed to provide the functionality described herein. One or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions to implement the functionality described herein for controller. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

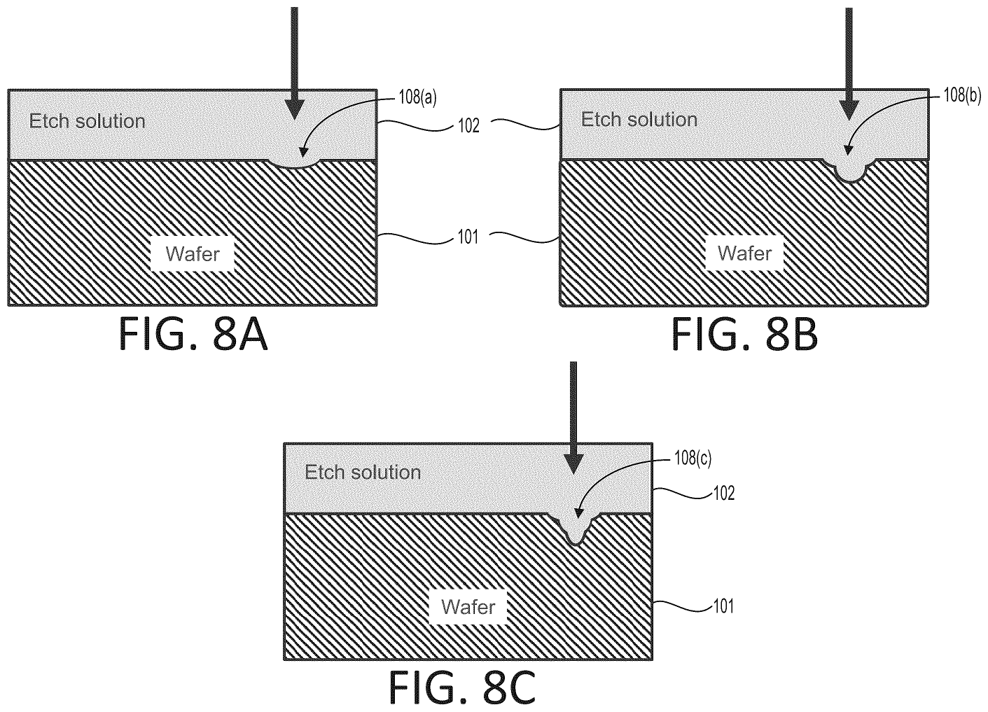

In an embodiment, a continuous heat energy may cause a lateral heat conduction in the liquid etch solution 102. In such a case, a pulse heat energy can be used to minimize the lateral heat conduction. FIGS. 8A-8C illustrate an example of a wet etching process using a pulse heat energy. As shown in FIGS. 8A-8C, the lateral etched portion of the semiconductor wafer 101 can be gradually reduced from 108(a) to 108(c).

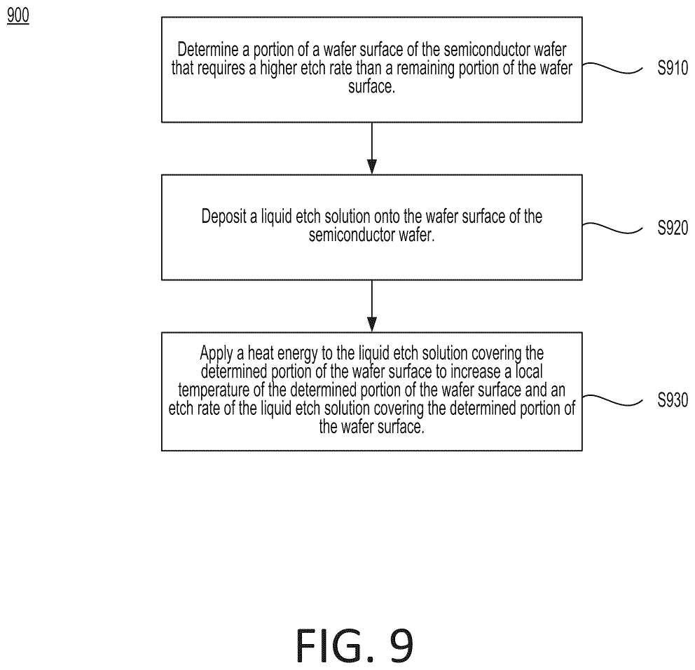

FIG. 9 illustrates a flowchart outlining a semiconductor process 900 for wet etching a semiconductor wafer (e.g., the semiconductor wafer 101) according to an embodiment of the disclosure. The semiconductor process 900 can be implemented by a controller (e.g., the controller 180 or 240) of a wafer processing system (e.g., the wafer processing system 100 or 200). The semiconductor process 900 can be implemented as instructions stored in a non-transitory computer-readable medium. When executed by for example the controller of the wafer processing system, the instructions can cause the wafer processing system to perform the semiconductor process 900. The semiconductor process 900 may start at step S910.

At step S910, the semiconductor process 900 can determine a portion of a wafer surface of the semiconductor wafer that requires a higher etch rate than a remaining portion of the wafer surface. Then, the semiconductor process 900 can proceed to step S920.

At step S920, the semiconductor process 900 can deposit a liquid etch solution onto the wafer surface of the semiconductor wafer. Then, the semiconductor process 900 can proceed to step S930.

At step S930, the semiconductor process 900 can apply a heat energy to the liquid etch solution covering the determined portion of the wafer surface to increase a local temperature of the determined portion of the wafer surface and an etch rate of the liquid etch solution covering the determined portion of the wafer surface. It is noted that the semiconductor process 900 can include a rinse process and/or a drying process in various embodiments.

In an embodiment, the heat energy can be applied via a light source to the liquid etch solution covering the determined portion of the wafer surface. A light frequency of the light source is selected such that the determined portion of the wafer surface has a higher light absorption than the liquid etch solution.

In an embodiment, the light source can include a laser or an LED array.

In an embodiment, the light source can irradiate the liquid etch solution covering the determined portion of the wafer surface through a patterning mask.

In an embodiment, an intensity of the light source can be modulated based on etch data from a previous etch process.

In an embodiment, an intensity of the light source can be modulated based on a real-time temperature measurement of the wafer surface.

In an embodiment, an intensity of the light source can be modulated based on a topography measurement of the wafer surface.

In an embodiment, the semiconductor wafer can be sandwiched between two functional plates of a wafer processing system. In an example, one of the function plates can include a heater, and the heat energy can be applied to the liquid etch solution covering the determined portion of the wafer surface via the heater of the one of the functional plates of the wafer processing system. In an example, one of the functional plates can be transparent, and the heat energy can be applied to the liquid etch solution covering the determined portion of the wafer surface via a light source illuminating through the transparent functional plate.

In an embodiment, the semiconductor process 900 can determine the portion of the wafer surface by performing a topography measurement for the wafer surface and determining a dwelling time and a location for applying the heat energy based on the topography measurement.

In an embodiment, the semiconductor wafer remains stationary during the heat energy is applied to the liquid etch solution covering the determined portion of the wafer surface.

Aspects of the disclosure provides a wafer processing system for etching a semiconductor wafer. The wafer processing system includes a controller configured to determine a portion of a wafer surface of the semiconductor wafer that requires a higher etch rate than a remaining portion of the wafer surface. The controller can control a chemical dispense nozzle to deposit a liquid etch solution onto the wafer surface of the semiconductor wafer. The controller is further configured to control a heating device to apply a heat energy to the liquid etch solution covering the determined portion of the wafer surface to increase a local temperature of the determined portion of the wafer surface and an etch rate of the liquid etch solution covering the determined portion of the wafer surface.

In an embodiment, the heating device can be a light source. A light frequency of the light source is selected such that the determined portion of the wafer surface has a higher light absorption than the liquid etch solution.

In an embodiment, the light source can include a laser or an LED array.

In an embodiment, the light source can irradiate the liquid etch solution covering the determined portion of the wafer surface through a patterning mask.

In an embodiment, an intensity of the light source can be modulated based on etch data from a previous etch process.

In an embodiment, an intensity of the light source can be modulated based on a real-time temperature measurement of the wafer surface.

In an embodiment, an intensity of the light source can be modulated based on a topography measurement of the wafer surface.

In an embodiment, the semiconductor wafer can be sandwiched between two functional plates of the wafer processing system. In an example, the heating device can be disposed in one of the two functional plates of the wafer processing system. In an example, one of the functional plates can be transparent, and the heat energy can be applied to the liquid etch solution covering the determined portion of the wafer surface via a light source illuminating through the transparent functional plate.

In an embodiment, the controller can determine the portion of the wafer surface by performing a topography measurement for the wafer surface and determining a dwelling time and a location for applying the heat energy based on the topography measurement.

In an embodiment, the semiconductor wafer can remain stationary during the heat energy is applied to the liquid etch solution covering the determined portion of the wafer surface.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A method of etching a semiconductor wafer, the method comprising:
determining a portion of a wafer surface of the semiconductor wafer that requires a higher etch rate than a remaining portion of the wafer surface;
depositing a liquid etch solution onto the wafer surface of the semiconductor wafer; and
applying a heat energy to the liquid etch solution covering the determined portion of the wafer surface to increase a local temperature of the determined portion of the wafer surface and an etch rate of the liquid etch solution covering the determined portion of the wafer surface.

2. The method of claim 1, wherein the heat energy is applied via a light source to the liquid etch solution covering the determined portion of the wafer surface, a light frequency of the light source being selected such that the determined portion of the wafer surface has a higher light absorption than the liquid etch solution.

3. The method of claim 2, wherein the light source includes a laser or a light emitting diode (LED) array.

4. The method of claim 2, wherein the light source irradiates the liquid etch solution covering the determined portion of the wafer surface through a patterning mask.

5. The method of claim 2, wherein an intensity of the light source is modulated based on etch data from a previous etch process.

6. The method of claim 2, wherein an intensity of the light source is modulated based on a real-time temperature measurement of the wafer surface.

7. The method of claim 2, wherein an intensity of the light source is modulated based on a topography measurement of the wafer surface.

8. The method of claim 1, wherein the heat energy is applied to the liquid etch solution covering the determined portion of the wafer surface via a heater disposed in a functional plate of a wafer processing system.

9. The method of claim 1, wherein the determining the portion of the wafer surface comprises:
performing a topography measurement for the wafer surface; and
determining a dwelling time and a location for applying the heat energy based on the topography measurement.

10. The method of claim 1, wherein the semiconductor wafer remains stationary during the heat energy is applied to the liquid etch solution covering the determined portion of the wafer surface.

11. A wafer processing system for etching a semiconductor wafer, the processing system comprising:
a controller configured to
determine a portion of a wafer surface of the semiconductor wafer that requires a higher etch rate than a remaining portion of the wafer surface,
control a chemical dispense nozzle to deposit a liquid etch solution onto the wafer surface of the semiconductor wafer, and
control a heating device to apply a heat energy to the liquid etch solution covering the determined portion of the wafer surface to increase a local temperature of the determined portion of the wafer surface and an etch rate of the liquid etch solution covering the determined portion of the wafer surface.

12. The wafer processing system of claim 11, wherein the heating device is a light source, a light frequency of the light source being selected such that the determined portion of the wafer surface has a higher light absorption than the liquid etch solution.

13. The wafer processing system of claim 12, wherein the light source includes a laser or a light emitting diode (LED) array.

14. The wafer processing system of claim 12, wherein the light source irradiates the liquid etch solution covering the determined portion of the wafer surface through a patterning mask.

15. The wafer processing system of claim 12, wherein an intensity of the light source is modulated based on etch data from a previous etch process.

16. The wafer processing system of claim 12, wherein an intensity of the light source is modulated based on a real-time temperature measurement of the wafer surface.

17. The wafer processing system of claim 12, wherein an intensity of the light source is modulated based on a topography measurement of the wafer surface.

18. The wafer processing system of claim 11, wherein the heating device is disposed in a functional plate of the wafer processing system.

19. The wafer processing system of claim 11, wherein the controller determines the portion of the wafer surface by performing a topography measurement for the wafer surface and determining a dwelling time and a location for applying the heat energy based on the topography measurement.

20. The wafer processing system of claim 11, wherein the semiconductor wafer remains stationary during the heat energy is applied to the liquid etch solution covering the determined portion of the wafer surface.
